(19) United States
(12) Patent Application Publication
(10) Pub. No.: US 2017/0069513 A1
(43) Pub. Date: Mar. 9, 2017

(54) SEMICONDUCTOR CLEANING PROCESS SYSTEM AND METHODS OF MANUFACTURING SEMICONDUCTOR DEVICES

(71) Applicant: Samsung Electronics Co., Ltd., Suwon-si (KR)

(72) Inventors: Jung-Min OH, lncheon (KR); Mi-Hyun PARK, Seongnam-si (KR); ln-Gi KIM, Hwaseong-si (KR); Ji-Hoon JEONG, Suwon-si (KR); Seok-Hoon KIM, Seongnam-si (KR); Hyo-San LEE, Hwaseong-si (KR)

(73) Assignee: Samsung Electronics Co., Ltd., Suwon-si (KR)

(21) Appl. No.: 15/168,713

(22) Filed: May 31, 2016

(30) Foreign Application Priority Data
Sep. 8, 2015 (KR) 10-2015-0126736

(51) Int. Cl. H01L 21/67; B08B 3/08; C11D 7/34; C11D 11/00; C11D 7/32; H01L 21/02; B08B 3/14

(52) U.S. Cl. CPC H01L 21/67051; H01L 21/02057; B08B 3/08; B08B 3/14; C11D 11/0047; C11D 7/3209; C11D 7/34

(57) ABSTRACT

A semiconductor cleaning process system includes a process chamber configured to hold a semiconductor substrate, a cleaning solution supply unit configured to provide a cleaning solution to the process chamber, the cleaning solution including an organic fluoride, an organic acid and an organic solvent, a recycling unit configured to collect the cleaning solution discharged from the process chamber, a first concentration measuring unit configured to evaluate a fluorine concentration of a collected solution in the recycling unit, and a sub-cleaning solution supply unit configured to provide the organic fluoride to the cleaning solution supply unit based on the fluorine concentration evaluated by the first concentration measuring unit.

### CROSS-REFERENCE TO RELATED APPLICATION

This application claims priority under 35 USC §119 to Korean Patent Application No. 10-2015-0126736, filed on Sep. 8, 2015 in the Korean Intellectual Property Office (KIPO), the contents of which incorporated by reference herein in their entirety.

### FIELD

Example embodiments relate to semiconductor cleaning process systems and/or methods of manufacturing semiconductor devices. More particularly, example embodiments relate to semiconductor cleaning process systems based on an organic system, and/or methods of manufacturing semiconductor devices utilizing the same.

### BACKGROUND

During fabrication of a semiconductor device, organic residues may be generated during various processes including, e.g., an etching process, an ion-implantation process, a photo-lithography process, etc. Thus, a cleaning process for removing the organic residues may be performed between unit processes of the semiconductor device fabrication.

Cleaning process conditions for improving a cleaning efficiency and reducing or substantially preventing damages of a semiconductor substrate, a gate structure, an insulation structure, etc., have been researched.

### SUMMARY

Example embodiments provide a semiconductor cleaning process system having improved efficiency and reliability.

Example embodiments provide a semiconductor cleaning process system having improved efficiency and reliability utilizing the semiconductor cleaning process system.

Example embodiments relate to a semiconductor cleaning process system. The system includes a process chamber in which a semiconductor substrate is loaded, a cleaning solution supply unit providing a cleaning solution into the process chamber, the cleaning solution including at least one of an organic fluoride, an organic acid and an organic solvent, a recycling unit collecting the cleaning solution discharged from the process chamber, a first concentration measuring unit evaluating a fluorine concentration of a collected solution in the recycling unit, and a sub-cleaning solution supply unit providing the organic fluoride into the cleaning solution supply unit based on the fluorine concentration evaluated by the first concentration measuring unit.

In example embodiments, the organic fluoride may include an alkyl ammonium fluoride, and the organic acid includes an organic sulfonic acid.

In example embodiments, the cleaning solution supply unit may include a cleaning solution supply bath storing the cleaning solution, and a supply flow path providing the cleaning solution into the process chamber. The recycling unit may include a first recycling flow path collecting the cleaning solution from the process chamber, a recycling bath storing the collected solution from the first recycling flow path, and a second recycling flow path providing the collected solution from the recycling bath to the cleaning solution supply unit.

In example embodiments, the recycling unit may further include a filter in the middle of the first recycling flow path removing a moisture and a cleaning residues included in the collected solution.

In example embodiments, the system further include a control unit coupled to the first concentration measuring unit and the sub-cleaning solution supply unit. A compensation signal of the organic fluoride is transferred from the control unit to the sub-cleaning solution supply unit when the fluorine concentration is less than a threshold fluorine concentration pre-stored, desired or alternatively predetermined in the control unit. The control unit may be or include a memory having computer-readable instructions stored therein, and a processor configured to cut the computer-readable instructions.

In example embodiments, the sub-cleaning solution supply unit may include a sub-cleaning solution supply bath storing a crude organic fluoride solution, a sub-supply flow path providing the organic fluoride from the sub-cleaning solution supply bath to the cleaning solution supply unit, and a flow rate controller in the middle of the sub-supply flow path.

In example embodiments, the organic fluoride may be provided as a plurality of pulses by the flow rate controller.

In example embodiments, the system may further include a second concentration measuring unit evaluating a fluorine concentration of the cleaning solution. The second concentration measuring unit may be coupled to the cleaning solution supply unit.

In example embodiments, the control unit may be coupled to the second concentration measuring unit. A supply signal of the cleaning solution into the process chamber is transferred to the cleaning solution supply unit by the control unit when the fluorine concentration of the cleaning solution reaches a target fluorine concentration.

In example embodiments, the organic acid may be replenished through the sub-cleaning solution supply unit together with the organic fluoride.

In example embodiments, the sub-cleaning solution supply unit may include a first sub-cleaning solution supply unit storing and providing a crude organic fluoride solution, and a second sub-cleaning solution supply unit storing and providing a crude organic acid solution.

In example embodiments, an amount of the organic acid of the cleaning solution stored in the cleaning solution supply unit may be maintained in a range from about 4 weight percent to about 12 weight percent based on a total weight of the cleaning solution.

In example embodiments, the semiconductor substrate may include germanium or a group III-V compound.

Example embodiments relate to a semiconductor cleaning process system. The system may include a process chamber in which a semiconductor substrate is loaded, a cleaning solution supply unit providing an organic cleaning solution into the process chamber, the organic cleaning solution including an organic fluoride, an organic acid and an organic solvent, the organic cleaning solution being substantially devoid of water, a recycling unit collecting the organic cleaning solution discharged from the process chamber, a concentration measuring unit evaluating a fluorine concentration of a collected solution in the recycling unit, and a sub-cleaning solution supply unit providing a mixture consisting essentially of the organic fluoride and the organic acid into the cleaning solution supply unit based on the fluorine concentration evaluated by the concentration measuring unit.

In example embodiments, an organic acid concentration of the collected solution may also be evaluated by the concentration measuring unit.

In example embodiments, the organic acid may be replenished by the sub-cleaning solution supply unit by a desired, or alternatively predetermined ratio with respect to an initial amount of the organic acid included in the organic cleaning solution.

Example embodiments relate to a method of manufacturing a semiconductor device. In the example method, an isolation layer may be formed on a substrate to form an active pattern from the substrate. A gate structure may be formed on the active pattern. A source/drain layer may be formed at an upper portion of the substrate adjacent to the gate structure. Cleaning treatments may be performed using a cleaning solution that may include an organic fluoride after forming the active pattern, after forming the gate structure and after forming the source/drain layer. A feed-back of a fluorine concentration may be provided after a previous cleaning treatment of the cleaning treatments to control a condition of a subsequent cleaning treatment of the cleaning treatments.

In example embodiments, the isolation layer may be recessed to expose an upper portion of the active pattern so that an active fin may be defined. The cleaning treatments may further include a cleaning treatment after forming the active fin.

In example embodiments, in forming the gate structure, a dummy gate structure crossing the active fin may be formed. A spacer may be formed on a sidewall of the dummy gate structure. The dummy gate structure may be removed to form a trench defined by an inner wall of the spacer. The gate structure may be formed in the trench. The cleaning treatments may further include a cleaning treatment after forming the trench.

In example embodiments, in providing the feed-back, the organic fluoride may be replenished in a cleaning solution used for the subsequent cleaning treatment.

Example embodiments relate to a cleaning system that includes a cleaning solution supplier configured to supply an organic cleaning solution into a process chamber, a collector configured to collect the organic cleaning solution from the process chamber, a concentration measuring unit configured to measure a fluorine concentration and an acid concentration of the collected organic cleaning solution, and a first sub-cleaning solution supplier configured to supply organic fluoride into the cleaning solution supplier based on the measured fluorine concentration. The organic cleaning solution is substantially devoid of an inorganic compound.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIG. 1 is a schematic view illustrating a construction of a semiconductor cleaning process system in accordance with example embodiments;

FIG. 2 is a schematic view illustrating a construction of a semiconductor cleaning process system in accordance with example embodiments;

FIG. 3 is a flow chart illustrating a semiconductor cleaning process in accordance with example embodiments;

FIG. 4 is a flow chart illustrating a semiconductor cleaning process in accordance with example embodiments;

FIG. 5 is a graph showing a relation between an etching rate and a residue removal capability with respect to an acid content;

FIG. 6 is a flow chart illustrating a semiconductor cleaning process in accordance with some example embodiments; and

FIGS. 7 to 21 are top plan views and cross-sectional views illustrating a method of manufacturing a semiconductor device.

### DESCRIPTION OF EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawing figures, the dimensions of layers and regions may be exaggerated for clarity of illustration. Like reference numerals refer to like elements throughout. The same reference numbers indicate the same components throughout the specification.

When the terms “about” or “substantially” are used in this specification in connection with a numerical value, it is intended that the associated numerical value include a tolerance of ±10% around the stated numerical value. Moreover, when reference is made to percentages in this specification, it is intended that those percentages are based on weight, i.e., weight percentages. The expression “up to” includes amounts of zero to the expressed upper limit and all values therebetween. When ranges are specified, the range includes all values therebetween such as increments of 0.1%. Moreover, when the words “generally” and “substantially” are used in connection with geometric shapes, it is intended that precision of the geometric shape is not required but that latitude for the shape is within the scope of the disclosure. Although the tubular elements of the embodiments may be cylindrical, other tubular cross-sectional forms are contemplated, such as square, rectangular, oval, triangular and others.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

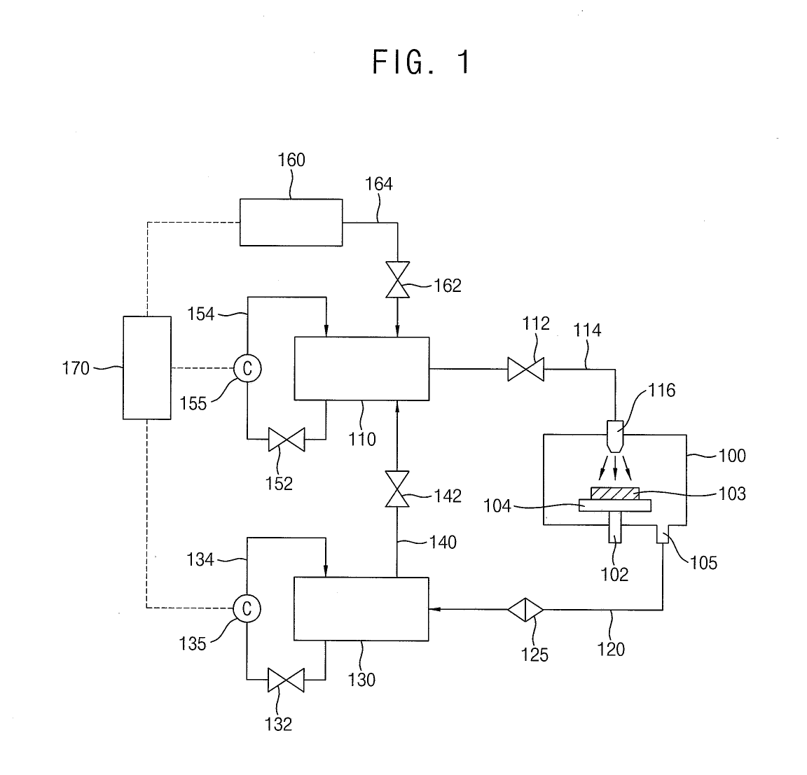

FIG. 1 is a schematic view illustrating a construction of a semiconductor cleaning process system in accordance with example embodiments.

Referring to FIG. 1, the cleaning process system may include a process chamber 100, a cleaning solution supply unit and a recycling unit.

A plate 104 for loading a substrate 103 may be placed in the process chamber 100. The plate 104 may be coupled to a rotating chuck 102. In some embodiments, the plate 104 may include a plurality of slots, and the substrate 103 may be placed on each or on one or more slot. A cleaning solution may be injected to a plurality of the substrates 103 while rotating the substrates 103 to perform a cleaning process.

For example, the substrate 103 may include a semiconductor wafer. In some embodiments, the substrate 103 may include germanium (Ge) or germanium-silicon (Ge—Si). In some embodiments, the substrate 103 may include a group III-V compound, e.g., InP, GaP, GaAs, GaSb, or the like.

Various structures such as an impurity region, an insulation structure, a conductive structure, etc., may be formed on the substrate 103, and the substrate 103 may be loaded into the process chamber 100.

The cleaning solution supply unit may include a cleaning solution supply bath 110, a supply flow path 114 and a first flow rate controller 112.

The cleaning solution for removing residues generated on the substrate 103 may be stored in the cleaning solution supply bath 110.

The residues may include contaminants generated from a unit process of a semiconductor fabrication, and may include organic residues. For example, the organic residues may include photoresist residues generated during a photo-lithography process, and polymer residues created from a gas phase etching process or a dry etching process using a carbon-based etching gas.

The cleaning solution may be an organic-based cleaning solution. In some embodiments, the cleaning solution may be an organic cleaning solution including or consisting essentially of organic components. In some embodiments, the organic cleaning solution may be substantially devoid of water such as deionized water.

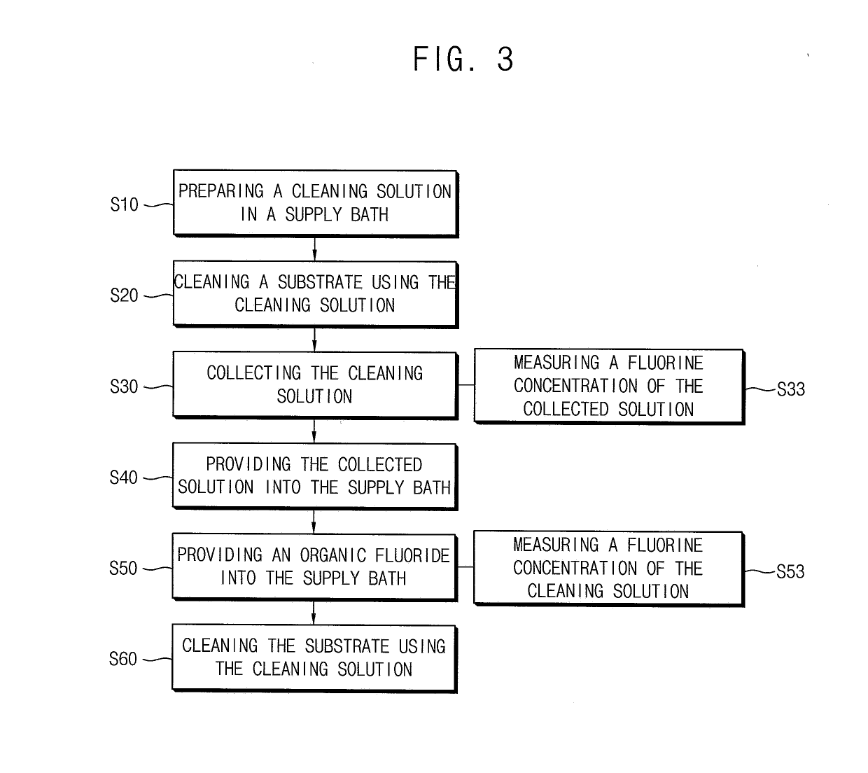

In some, embodiments, the organic cleaning solution may include an organic fluoride, an organic acid and an organic solvent. Components of the organic cleaning solution may be described in detail with descriptions on a cleaning process with reference to FIG. 3.

The cleaning solution stored in the cleaning solution supply bath 110 may be injected into the process chamber 100 through the supply flow path 114 to perform the cleaning process on the substrate 103. For example, the cleaning solution may be injected on the substrate 103 through an injector 116 that may be at least partially inserted in the process chamber 100.

The first flow rate controller 112 may be disposed at a portion of, or in the middle of, the supply flow path 114 to control a supply amount of the cleaning solution. The first flow rate controller 112 may substantially serve as a pump.

The process chamber 100 may include an outlet 105, and the cleaning solution gathering at a lower portion of the process chamber 100 after the cleaning process may be discharged to the recycling unit through the outlet 105.

The recycling unit may include a first recycling flow path 120, a recycling bath 130 and a second recycling flow path 140.

The cleaning solution discharged through the outlet 105 may be provided into the recycling bath 130 through the first recycling flow path 120. Accordingly, a collected solution for a cleaning process recycle may be stored in the recycling bath 130.

In example embodiments, a filter 125 may be disposed at a portion of, or in the middle of, the first recycling flow path 120. Moisture (water) and any residues mixed in the cleaning solution that may be included in the collected solution provided into the recycling bath 130 may be filtered through the filter 125. A water component that may be included in the cleaning process system may be removed by the filter 125 to realize a substantially organic-based system.

The filter 125 may include, e.g., a membrane, a moisture absorbent, an ultrafilter, etc.

The recycling bath 130 may be coupled to a first circulation flow path 134. In example embodiments, a first concentration measuring unit 135 may be disposed at a portion of, or in the middle of the first circulation flow path 134. For example, a desired, or alternatively predetermined or given amount of the collected solution may be extracted from the recycling bath 130 to the first concentration measuring unit 135 using a first circulation pump 132.

In example embodiments, a fluorine concentration of the collected solution may be evaluated through the first concentration measuring unit 135. The fluorine concentration evaluated by the first concentration measuring unit 135 may be transferred to a control unit 170 so that a feed-back may be provided for a subsequent process.

The collected solution stored in the recycling bath 130 may be provided again into the cleaning solution supply bath 110 through the second recycling flow path 140. A second flow rate controller 142 may be disposed at a portion of, or in the middle of the second recycling flow path 140 so that a supply amount of the collected solution into the cleaning solution supply bath 110 may be controlled.

In example embodiments, the cleaning solution supply bath 110 may be coupled to a sub-cleaning solution supply unit including a sub-supply flow path 164 and a sub-cleaning solution supply bath 160. An organic fluoride for a compensation of a fluorine component into the cleaning solution supply bath 110 may be stored in the sub-cleaning solution supply bath 160.

In example embodiments, if the fluorine concentration transferred from the first concentration measuring unit 135 to the control unit 170 is below a threshold fluorine concentration pre-stored, desired, or alternatively predetermined in the control unit 170, a compensation signal of the organic fluoride may be transferred to the sub-cleaning solution supply bath 160 by the control unit 170. Accordingly, the organic fluoride may be provided into the cleaning solution supply bath 110 from the sub-cleaning solution supply bath 160 through the sub-supply flow path 164. In some embodiments, a third flow rate controller 162 may be disposed in the middle of the sub-supply flow path 164 to control a compensation amount of the organic fluoride.

In some example embodiments the cleaning solution supply bath 110 may be coupled to a second circulation flow path 154. A second concentration measuring unit 155 may be disposed in the middle of the second circulation flow path 154. For example, a desired or alternatively predetermined or given amount of the cleaning solution may be extracted from the cleaning solution supply bath 110 to the second concentration measuring unit 155 using a second circulation pump 152.

In example embodiments, a fluorine concentration of the cleaning solution may be evaluated through the second concentration measuring unit 155. The fluorine concentration evaluated by the second concentration measuring unit 155 may be transferred to the control unit 170. For example, if the fluorine concentration of the cleaning solution stored in the cleaning solution supply bath 110 is greater than a target fluorine concentration pre-stored, desired, or alternatively predetermined in the control unit 170, a supply signal of the cleaning solution may be transferred to the cleaning solution supply bath 110 through the control unit 170. Accordingly, the cleaning solution may be provided from the cleaning solution supply bath 110 to the process chamber 100 so that the cleaning process may be performed again.

The first and second concentration measuring units 135 and 155 may include various types of concentration measuring devices such as a conductivity measuring type, an absorbance measuring type, an electrode type, etc.

In some example embodiments, the organic acid may be stored in the sub-cleaning solution supply bath 160 together with the organic fluoride. In this case, the organic acid may also be provided into the cleaning solution supply bath 110 in response to a compensation signal from the control unit 170. The cleaning capability of the cleaning solution may be recovered more rapidly by the addition of the organic acid.

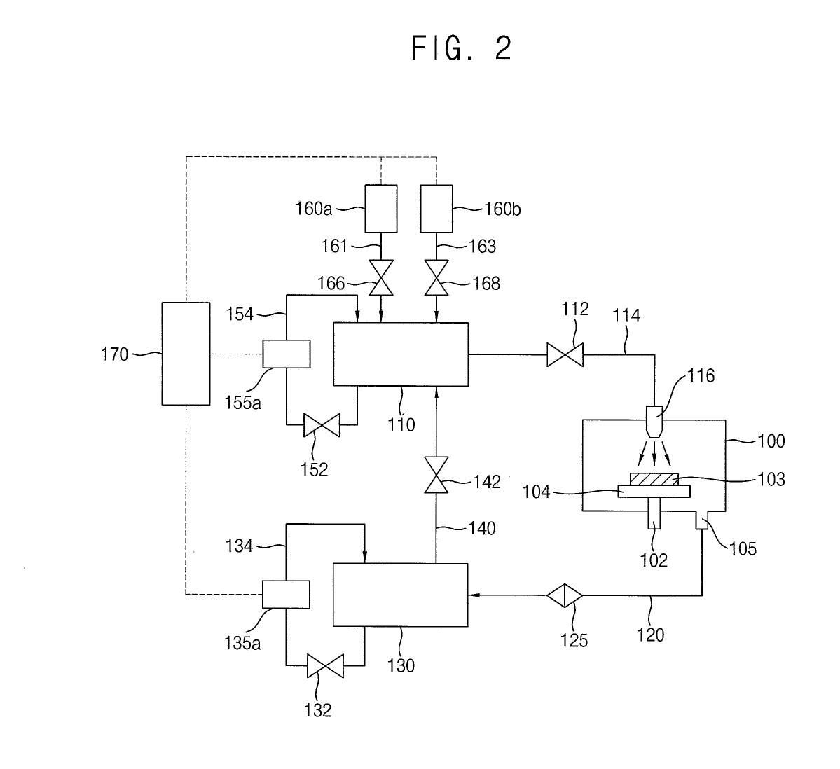

FIG. 2 is a schematic view illustrating a construction of a semiconductor cleaning process system in accordance with example embodiments. The cleaning process system of FIG. 2 may have a construction substantially the same as or similar to the construction of the cleaning process system illustrated with reference to FIG. 1, except for structures of a sub-cleaning solution supply unit and a concentration measuring unit. Thus, detailed descriptions on repeated elements and structures are omitted herein.

Referring to FIG. 2, a first sub-cleaning solution supply bath 160a for a compensation of an organic fluoride and a second sub-cleaning solution supply bath 160b for a compensation of an organic acid may be individually or separately included in a sub-cleaning solution supply bath of the cleaning process system. The first sub-cleaning solution supply bath 160a and the second sub-cleaning solution supply bath 160b may be coupled to the cleaning solution supply bath 110 through a first sub-supply flow path 161 and a second sub-supply flow path 163, respectively.

A third flow rate controller 166 may be disposed at a portion of, or in the middle of the first sub-supply flow path 161 to control an amount of the organic fluoride provided into the cleaning solution supply bath 110. A fourth flow rate controller 168 may be disposed at a portion of, or in the middle of, the second sub-supply flow path 163 to control an amount of the organic acid provided into the cleaning solution supply bath 110. The third and fourth flow rate controller 166 and 168 may substantially serve as pumps.

In some embodiments, a desired, or alternatively predetermined amount of the organic acid may be provided into the cleaning solution supply bath 110 through the second sub-cleaning solution supply bath 160b and the second sub-supply flow path 163 whenever the organic fluoride is provided from the first sub-cleaning solution supply bath 160a.

In some embodiments, if an acid concentration of the cleaning solution stored in the cleaning solution supply bath 110 is excessively increased, a supply of the organic acid may be ceased by the control unit 170, and substantially only the organic fluoride may be supplied.

An acid concentration may be measured by first and second concentration measuring units 135a and 155a together with a fluorine concentration. In some embodiments, the first and second concentration measuring units 135a and 155a may further include a pH measuring device for measuring the acid concentration.

For example, if an acid concentration of the collected solution stored in the recycling bath 130, which may be measured by the first concentration measuring unit 135a, is below a desired, or alternatively predetermined threshold concentration, a compensation signal of the organic acid may be transferred to the second sub-cleaning solution supply bath 160b and/or the second sub-supply flow path 163 through the control unit 170.

If a fluorine concentration and an acid concentration of the cleaning solution stored in the cleaning solution supply bath 110, which may be measured by the second concentration measuring unit 155a, are substantially the same as or greater than a target fluorine concentration and a target acid concentration, a supply signal of the cleaning solution may be transferred to the cleaning solution supply bath 110 and/or the supply flow path 114 through the control unit 170 so that the cleaning process may be repeated.

FIG. 3 is a flow chart illustrating a semiconductor cleaning process in accordance with example embodiments. Hereinafter, detailed descriptions on the cleaning process are provided with reference to FIGS. 1 and 3.

Referring to FIG. 3, e.g., in operation S10, a cleaning solution may be prepared in the cleaning solution supply bath 110. The substrate 103 on which the cleaning process may be performed may be loaded on the plate 104 placed in the process chamber 100.

The cleaning solution may include at least one of an organic fluoride, an organic acid and an organic solvent. In some embodiments, the cleaning solution may be an organic solution consisting essentially of organic components.

In some embodiments, the organic fluoride may include an alkyl ammonium fluoride such as tetra-alkyl ammonium fluoride. For example, the alkyl ammonium fluoride may be represented as a chemical formula of FN((CH₂)ₙCH₃)₄.

In the chemical formula, n may be an integer between 2 and 10.

The organic fluoride may be included in an amount ranging from about 1 weight percent (wt %) to about 10 wt %, based on a total weight of the cleaning solution. If the amount of the organic fluoride is less than about 1 wt %, a cleaning rate may be excessively reduced. If the amount of the organic fluoride exceeds about 10 wt %, the substrate 103 or a structure formed on the substrate 103 (e.g., a silicon oxide layer) may be damaged.

The organic acid may react with the organic fluoride to form a fluorine-containing active species serving as a cleaning agent. Additionally, the organic acid may provide a passivation on a surface of the substrate 103 or on the structure formed or present on the substrate 103. Accordingly, the substrate 103 or the structure formed or present thereon may be substantially prevented from being damaged or etched by the fluorine-containing active species. For example, the organic acid may serve as an activator for the organic fluoride, and also serve as an inhibitor for reducing or substantially preventing an etching damage.

In some embodiments, the organic acid may include an organic sulfonic acid. For example, the organic sulfonic acid may include a relatively hydrophobic organic moiety and a relatively hydrophilic sulfonate moiety. The sulfonate moiety may provide a passivation on, e.g., a silicon oxide layer that may be hydrophilic, and the organic moiety may interact with the organic fluoride to facilitate a generation of the fluorine-containing active species.

The organic sulfonic acid may include, e.g., methane sulfonic acid, ethane sulfonic acid, 1-propane sulfonic acid, para-toluene sulfonic acid or benzene sulfonic acid. The above acids may be used alone or in a combination thereof.

The organic acid may be included in an amount ranging from about 1 wt % to about 20 wt %, based on the total weight of the cleaning solution. If the amount of the organic acid is less than about 1 wt %, the cleaning rate may be reduced. If the amount of the organic acid exceeds about 20 wt %, a productivity of the semiconductor fabrication may be reduced, and the substrate 103 and the structure may be damaged. In some embodiments, the amount of the organic acid may be in a range from about 4 wt % to about 12 wt %.

The organic solvent may include a polar solvent having an improved solubility with respect to the organic fluoride and the organic acid as mentioned above. In example embodiments, the organic solvent may include an ester-based solvent and/or a lactone-based solvent.

The ester-based solvent may include, e.g., 3-methoxy propionic acid methyl or 3-ethoxy propionic acid ethyl. The lactone-based solvent may include, e.g., gamma-butyrolactone. These may be used alone or in a combination thereof. In some embodiments, the organic solvent may include an alcohol-based solvent such as methanol, ethanol, propanol, hexanol, cyclohexanol, diacetone alcohol, tetra furfuryl alcohol, etc.

The organic solvent may be included as a remainder of the cleaning solution except for the organic fluoride and the organic acid. For example, the organic solvent may be included in an amount ranging from about 70 wt % to about 98 wt %, based on the total weight of the cleaning solution. In some embodiments, the amount of the organic solvent may be in a range from about 78 wt % to about 95 wt %.

The substrate 103 may be a Si-substrate, a Si—Ge substrate or a Ge substrate. In some embodiments, the substrate 103 may include a Si—Ge channel layer or a Ge channel layer grown from the Si-substrate. In embodiments, the substrate 103 may include a group compound such as InP, GaP, GaAs, GaSb, etc.

The structure formed on the substrate 103 may include an insulation structure formed of or include silicon nitride, silicon oxide, silicon oxynitride, etc., and/or a conductive structure formed of or including a metal, a metal nitride, a metal silicide, doped polysilicon, etc. An impurity region may be formed at a specific area of the substrate 103.

Ge and/or the group III-V compound may be employed as a material for the substrate 103 to improve channel mobility in a semiconductor device. In this case, the substrate 103 may be damaged by the cleaning process more easily than in the Si substrate. However, according to example embodiments, the organic fluoride and the organic acid may be utilized instead of an inorganic acid such as a fluoric acid to substantially prevent the substrate 103 from being damaged during the cleaning process.

For example, in operation S20, the cleaning solution may be injected onto the substrate 103 to perform a cleaning treatment.

The cleaning solution may be provided into the process chamber 100 from the cleaning solution supply bath 110 through the supply flow path 114. A supply amount of the cleaning solution may be controlled by the first flow rate controller 112. In some embodiments, a plurality of the substrates 103 may be concurrently treated while rotating the plate 104.

For example, in operation S30, the cleaning solution may be collected from the process chamber 100. After the cleaning treatment, the cleaning solution remaining in the process chamber 100 may be stored in the recycling bath 130 through the outlet 105 and the first recycling flow path 120. Moistures and residues discharged with the cleaning solution may be removed by the filter 125.

The moisture such as water may be removed by the filter 125, and a hydrophobicity of the cleaning solution may be ensured to substantially prevent the substrate 103 from being damaged by the cleaning solution.

For example, in operation S33, a fluorine concentration of the collected solution may be measured. In example embodiments, a desired, or alternatively predetermined or given amount of the collected solution may be extracted from the recycling bath 130 through the first circulation flow path 134 and the first circulation pump 132, and may be provided into the first concentration measuring unit 135 to evaluate the fluorine concentration of the collected solution. The fluorine concentration may be transferred to the control unit 170.

For example, in operation S40, the collected solution may be recycled from the recycling bath 130 to the cleaning solution supply bath 110 through the second recycling flow path 140. A supply flow rate of the collected solution may be controlled by the second flow rate controller 142.

If the fluorine concentration transferred from the first concentration measuring unit 135 is less than a threshold fluorine concentration, a compensation signal of an organic fluoride may be transferred from the control unit 170 to the sub-cleaning solution supply bath 160 in which a crude organic fluoride solution may be stored.

In some embodiments, the threshold fluorine concentration may be in a range from about 1% to about 50% of an initial fluorine concentration in the cleaning solution supply bath 110. In some embodiments, the threshold fluorine concentration may be in a range from about 10% to about 50% of the initial fluorine concentration.

For example, in operation S50, the organic fluoride may be provided into the cleaning solution supply bath 110.

In example embodiments, the crude organic fluoride solution stored in the sub-cleaning solution supply bath 160 may be provided into the cleaning solution supply bath 110 based on the compensation signal of the organic fluoride from the control unit 170. Accordingly, a refreshed cleaning solution by the collected solution and the organic fluoride may be stored in the cleaning solution supply bath 110.

In some embodiments, the organic fluoride may be supplied through the sub-supply flow path 164 as a pulse by the third flow rate controller 162. For example, a plurality of organic fluoride pulses may be supplied, for example sequentially supplied, based on the signal from the control unit 170.

For example, in operation S53, a fluorine concentration of the cleaning solution in the cleaning solution supply bath 110 may be evaluated by the second concentration measuring unit 155. A desired, or alternatively predetermined or given amount of the cleaning solution may be extracted through the second circulation flow path 154 and the second circulation pump 152, and may be provided into the second concentration measuring unit 155.

The organic fluoride pulse may be supplied into the cleaning solution supply bath 110 until the fluorine concentration evaluated by the second concentration measuring unit 155 reaches a target concentration that may be pre-stored, desired or alternatively predetermined in the control unit 170.

For example, in operation S60, the cleaning treatment on the substrate 103 may be repeated. In example embodiments, the refreshed cleaning solution may be provided from the cleaning solution supply bath 110 to the process chamber 100 to perform the cleaning process again. The cleaning solution having a recovered cleaning capability may be recycled to repeat the cleaning process, and an entire cleaning efficiency may be maintained while reducing a process cost.

In some embodiments, when the fluorine concentration evaluated by the second concentration measuring unit 155 is equal to or greater than the target concentration, a supply signal of the cleaning solution may be transferred to the cleaning solution supply bath 110 and/or the first flow rate controller 112.

For example, the target concentration may be in a range from about 80% to about 100% of the initial fluorine concentration in the cleaning solution supply bath 110.

In some example embodiments, a crude organic acid solution may be stored in the sub-cleaning solution supply bath 160 together with the crude organic fluoride solution. In this case, a mixture of the organic fluoride and the organic acid may be provided into the cleaning solution supply bath 110 through the sub-supply flow path 164.

As described above, the organic acid may serve as an activator for generating a fluorine-containing active species. Thus, the cleaning capability of the cleaning solution may be recovered through an interaction of the organic acid and the organic fluoride.

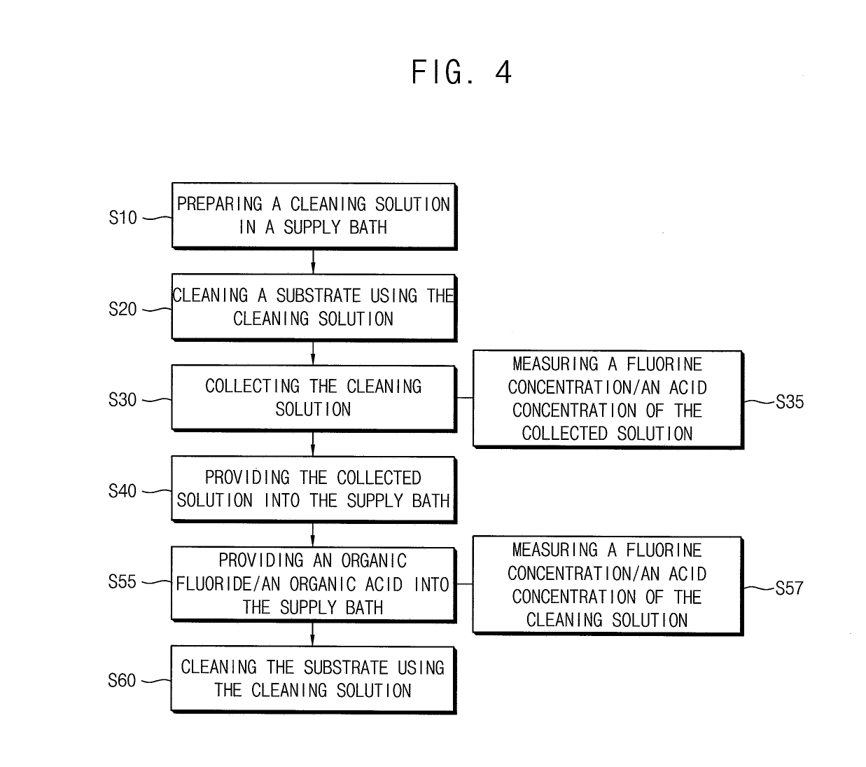

FIG. 4 is a flow chart illustrating a semiconductor cleaning process in accordance with example embodiments. Hereinafter, detailed descriptions on the cleaning process are provided with reference to FIGS. 2 and 4. Detailed descriptions on a system construction and a unit process substantially the same as or similar to the system construction and unit process illustrated with reference to FIGS. 1 and 3 are omitted herein.

Referring to FIG. 4, operations from S10 to S30 may be performed as described with reference to FIG. 3.

In example embodiments, in operation S35, a fluorine concentration and an acid concentration of a collected solution stored in the recycling bath 130 may be measured. For example, the fluorine concentration and the acid concentration may be individually evaluated by the first concentration measuring unit 135a illustrated in FIG. 2, and an information of the concentrations may be transferred to the control unit 170. The fluorine concentration and the acid concentration may be compared to a threshold fluorine concentration and a threshold acid concentration, respectively, in the control unit 170, and the control unit 170 may determine whether compensation signals are created based on the comparison.

For example, in operation S40, the compensation signals of an organic fluoride and an organic acid may be transferred to the first sub-cleaning solution supply bath 160a and the second sub-cleaning solution supply bath 160b, respectively, from the control unit 170, while recycling the collected solution into the cleaning solution supply bath 110. Accordingly, the organic fluoride and the organic acid may be provided, for example independently provided, into the cleaning solution supply bath 110 through the first sub-supply flow path 161 and the second sub-supply flow path 163.

In some embodiments, the organic fluoride and the organic acid may be converted as pulses by the third flow rate controller 166 and the fourth flow rate controller 168, respectively.

In some embodiments, the organic fluoride and the organic acid may be provided as desired, or alternatively predetermined amounts per one cycle of the cleaning treatment. For example, each or one or more of the organic fluoride and the organic acid may be compensated in an amount ranging from about 10% to about 20% of an initial amount in the cleaning solution per the one cycle.

For example, in operation S57, a fluorine concentration and an acid concentration of a refreshed cleaning solution in the cleaning solution supply bath 110 may be measured. As illustrated in FIG. 2, the fluorine concentration and the acid concentration may be evaluated by the second concentration measuring unit 155a, and a concentration information may be transferred to the control unit 170. When the fluorine concentration and the acid concentration are equal to or greater than a target fluorine concentration and a target acid concentration, respectively, pre-stored, desired or alternatively predetermined in the control unit 170, a supply signal of the cleaning solution may be transferred.

Accordingly, e.g., in operation S60, the refreshed cleaning solution may be provided from the cleaning solution supply bath 110 to the process chamber 100 to repeat the cleaning treatment.

According to example embodiments as described above, in a semiconductor cleaning process using the organic fluoride and the organic acid that may be relatively expensive, the cleaning solution may be recycled while maintaining target concentrations of the organic fluoride and/or the organic acid. Therefore, cleaning efficiency may be improved while reducing or substantially preventing damages of various structures of a semiconductor device.

FIG. 5 is a graph showing a relation between an etching rate and a residue removal capability with respect to an acid content. The etching rate may refer to an etching rate with respect to an oxide layer.

Specifically, tetrabutyl ammonium fluoride, methane sulfonic acid and gamma-butyrolactone were used as an organic fluoride, an organic acid and an organic solvent, respectively. The etching rate with respect to a silicon oxide layer and a cleaning capability with respect to photoresist residues were measured while changing the content of methane sulfonic acid. The etching rate is indicated as a triangle, and the cleaning capability is indicated as a quadrangle in FIG. 5.

Referring to FIG. 5, the etching rate and the residue removal capability (e.g., the cleaning capability) commonly increased until an acid content in a cleaning solution reached about 2 wt %. However, when the acid content exceeded about 2 wt %, the residue removal capability gradually increased and the etching rate began to decrease. When the acid content reached about 10 wt %, the etching rate was substantially zero. When the acid content exceeded about 12 wt %, the residue removal capability did not increase significantly and maintained a substantially constant state.

As shown in FIG. 5, an improved cleaning capability may be achieved by adding the organic acid in combination with an organic fluoride recycle while substantially preventing a substrate and other structures on the substrate from being etched in a cleaning process.

Further, the target acid concentration stored in the control unit 170 may be set in a range, e.g., from about 4 wt % to about 12 wt %, so that a reduced etching rate and an improved cleaning capability may be realized while repeating the cleaning process.

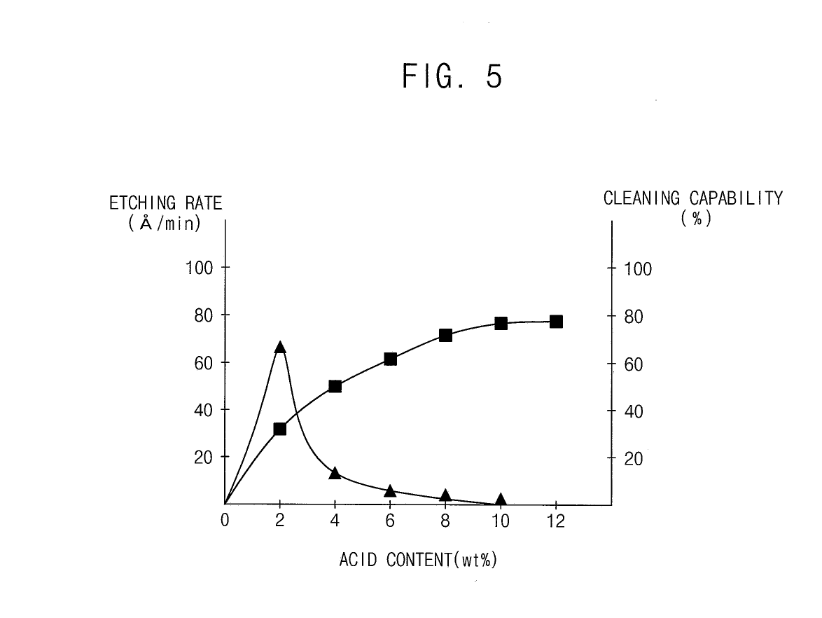

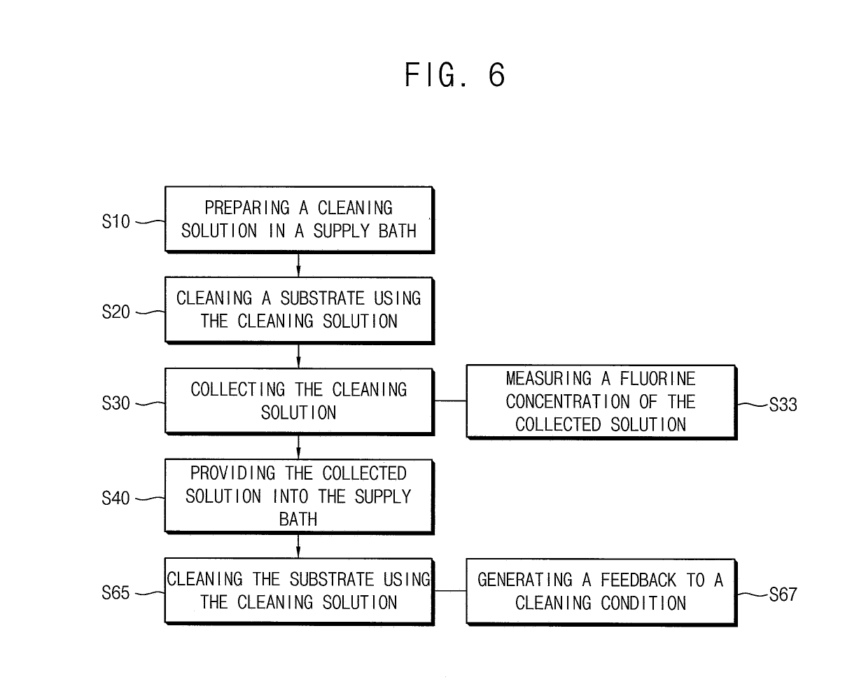

FIG. 6 is a flow chart illustrating a semiconductor cleaning process in accordance with some example embodiments. Detailed descriptions on a system construction and a unit process substantially the same as or similar to the system construction and unit process illustrated with reference to FIGS. 1 to 4 are omitted herein.

Referring to FIG. 6, unit processes substantially the same as or similar to operations S10 to S40 described with reference to FIG. 3 may be performed.

In example embodiments, when a cleaning treatment on the substrate 103 is performed again using a refreshed cleaning solution, a feed-back of a fluorine concentration of a collected solution measured in operation S33 may be generated so that a cleaning condition may be adjusted (e.g., in operation S67)

In some embodiments, if the fluorine concentration of the collected solution is less than a threshold fluorine concentration, a flow rate of the refreshed cleaning solution may be increased by the first flow rate controller 112. In an embodiment, a supply period of the refreshed cleaning solution may be increased, and a cleaning process period may be also increased.

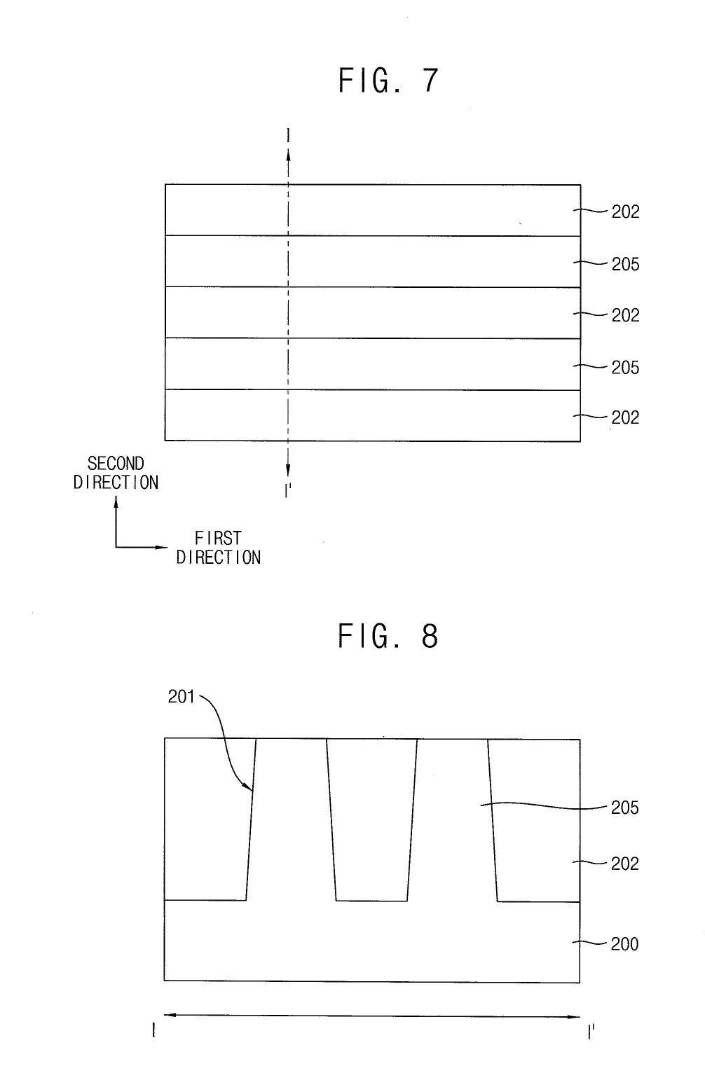

FIGS. 7 to 21 are top plan views and cross-sectional views illustrating a method of manufacturing a semiconductor device. For example, FIGS. 7 to 21 illustrate a method of manufacturing a semiconductor device that may include a fin field-effect transistor (FinFET).

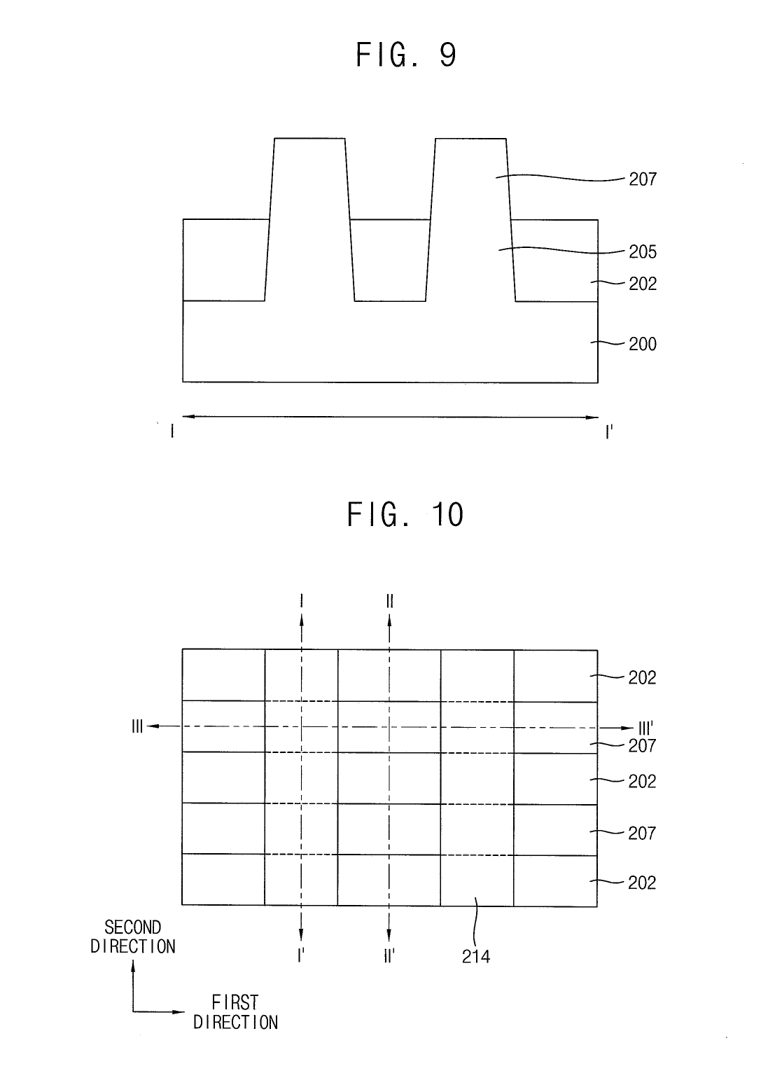

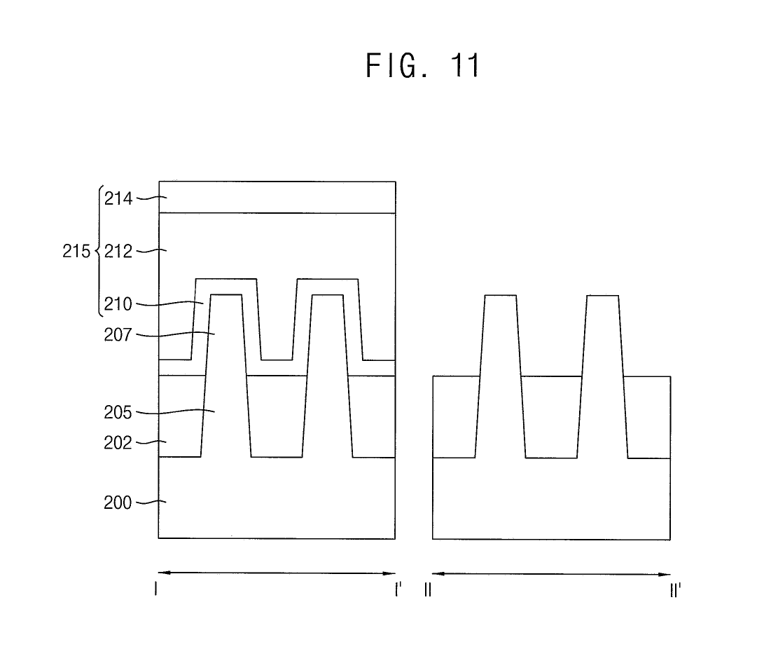

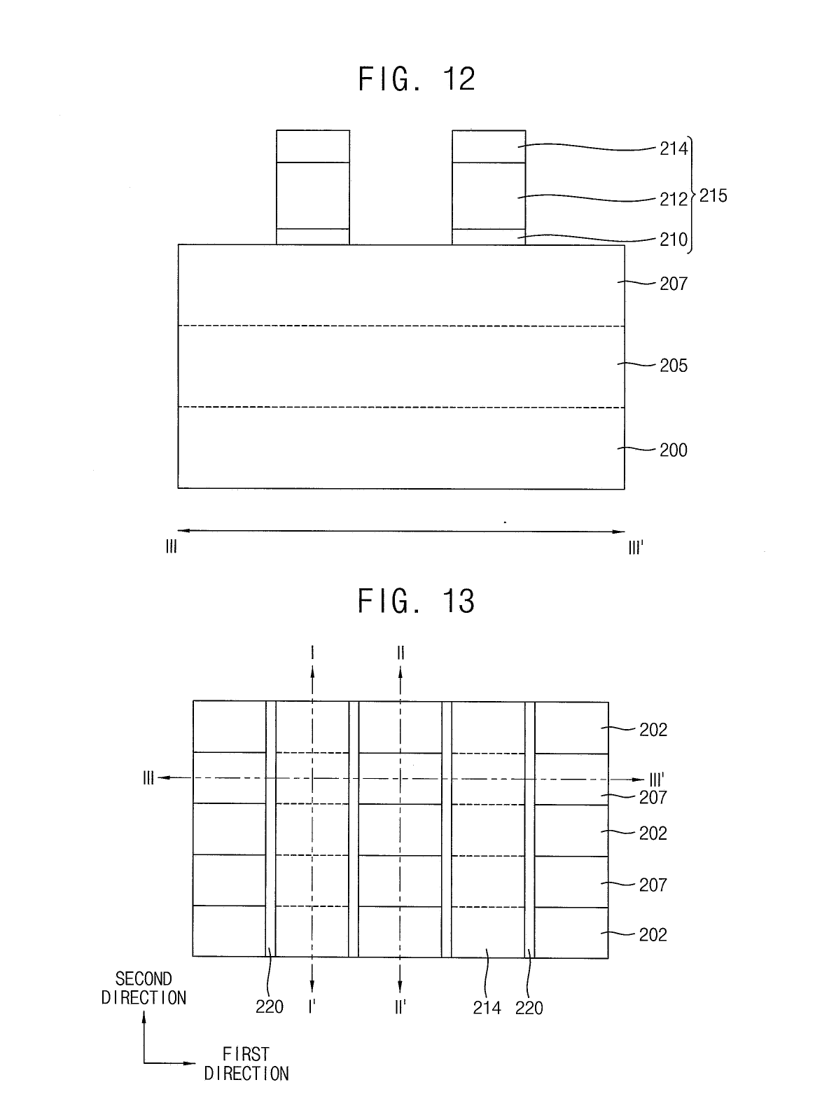

Specifically, FIGS. 7, 10 and 13 are top plan views illustrating the method. FIGS. 8 and 9 are cross-sectional views taken along a line I-I′ indicated in FIG. 7. FIGS. 11, 16 and 18 include cross-sectional views taken along lines I-I′ and II-II′ indicated in FIGS. 10 and 13. FIGS. 12, 14, 15, 17, 19, 20 and 21 are cross-sectional views taken along a line III-III′ indicated in FIGS. 10 and 13.

In FIGS. 7 to 21, two directions substantially parallel to a top surface of a substrate and substantially perpendicular to each other are referred to as a first direction and a second direction. The direction indicated by an arrow and a reverse direction thereof are considered as the same direction.

Detailed descriptions on the cleaning process system and/or the cleaning process described with reference to FIGS. 1 to 6 are omitted herein.

Referring to FIGS. 7 and 8, an active pattern 205 protruding from a substrate 200 may be formed.

The substrate 200 may include a semiconductor material such as Si, Ge, Si—Ge, or a group III-V compound such as InP GaP, GaAs, GaSb, etc. In some embodiments, the substrate 200 may include a silicon-on-insulator (SOI) substrate or a germanium-on-insulator (GOI) substrate.

In some example embodiments, the substrate 200 may include a channel layer formed from a silicon wafer by a epitaxial growth process using a germanium source gas such as germane (GeH₄) or germanium tetrachloride (GeCl₄). In this case, the channel layer may include Si—Ge or Ge.

In example embodiments, the active pattern 205 may be formed by a shallow trench isolation (STI) process. For example, an upper portion of the substrate 200 may be partially etched to form an isolation trench, and then an insulation layer sufficiently filling the isolation trench may be formed on the substrate 200. An upper portion of the insulation layer may be planarized by, e.g., a CMP process until a top surface of the substrate 200 may be exposed to form an isolation layer 202. The insulation layer may be formed of or include, e.g., silicon oxide.

A plurality of protrusions may be formed from the substrate 200 defined by the isolation layer 202. The protrusions may be defined as the active patterns 205. Each or one or more active pattern 205 may extend linearly in the first direction, and a plurality of the active patterns 205 may be formed along the second direction.

In some embodiments, after forming the active pattern 205, an ion-implantation process may be performed to form a well in the active pattern 205 and the substrate 200.

In example embodiments, a first cleaning treatment may be performed after forming the isolation trench, after a CMP process for forming the isolation layer 202 and/or after the ion-implantation process for forming the well.

The first cleaning treatment may be performed using the cleaning process system illustrated with reference to FIGS. 1 to 4. For example, a cleaning solution including an organic fluoride, an organic acid and an organic solvent may be injected from the cleaning solution supply bath 110 into the process chamber 100 in which the substrate 200 may be loaded. Etching residues, photoresist residues and/or residues generated from the substrate 200 during the ion-implantation process may be removed by the first cleaning treatment.

Referring to FIG. 9, an upper portion of the isolation layer 202 may be removed by, e.g., an etch-back process so that an upper portion of the active pattern 205 may be exposed. The upper portion of the active pattern 205 exposed from a top surface of the isolation layer 202 may be defined as an active fin 207. The active fin 207 may extend in the first direction, and a plurality of the active fins 207 may be arranged along the second direction.

In example embodiments, after the etch-back process, a second cleaning treatment may be further performed. As illustrated with reference to FIGS. 1 to 4, for example, a fluorine concentration of a collected solution after the first cleaning treatment may be measured, and the second cleaning treatment may be performed using a refreshed cleaning solution in which the organic fluoride, or a mixture of the organic fluoride and the organic acid may be replenished, based on a feed-back of an information of the fluorine concentration.

Referring to FIGS. 10, 11 and 12, a dummy gate structure 215 may be formed on the isolation layer 202 and the active fin 207.

For example, a dummy gate insulation layer, a dummy gate electrode layer and a dummy gate mask layer may be formed, for example sequentially formed, on the active fin 207 and the isolation layer 202. The dummy gate mask layer may be patterned by a photo-lithography process to form a dummy gate mask 214. The dummy gate electrode layer and the dummy gate insulation layer may be partially removed using the dummy gate mask 214 as an etching mask to form the dummy gate structure 215.

The dummy gate structure 215 may include a dummy gate insulation pattern 210, a dummy gate electrode 212 and the dummy gate mask 214 stacked, for example sequentially stacked, from the active fin 207 and the isolation layer 202.

For example, the dummy gate insulation layer may be formed of or include silicon oxide. The dummy gate electrode layer may be formed of or include polysilicon. The dummy gate mask layer may be formed of or include silicon nitride.

The dummy gate insulation layer, the dummy gate electrode layer and the dummy gate mask layer may be formed by a CVD process, a sputtering process or an atomic layer deposition (ALD) process. In an example embodiment, the dummy gate insulation layer may be formed by a thermal oxidation process on the active fin 207. In this case, the dummy gate insulation layer may be selectively formed on a top surface of the active fin 207.

As illustrated in FIG. 11, the dummy gate structure 215 may extend in the second direction, and may cross a plurality of the active fins 207. A plurality of the dummy gate structures 215 may be formed along the first direction.

In example embodiments, after forming the dummy gate structure 215, a third cleaning treatment may be further performed to remove etching residues. As illustrated with reference to FIGS. 1 to 4, for example, a fluorine concentration of a collected solution after the second cleaning treatment may be measured, and the third cleaning treatment may be performed using a refreshed cleaning solution in which the organic fluoride, or a mixture of the organic fluoride and the organic acid may be replenished, based on a feed-back of an information of the fluorine concentration.

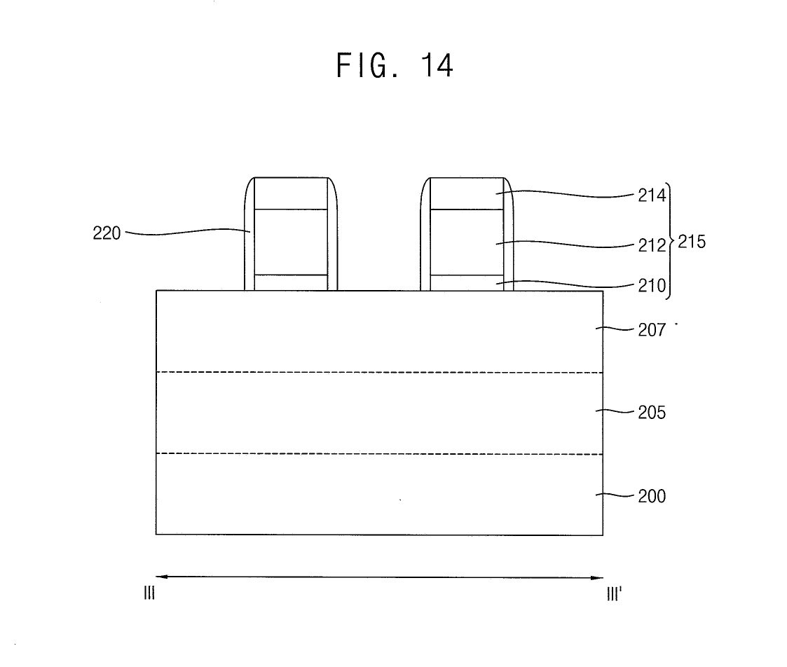

Referring to FIGS. 13 and 14, a gate spacer 220 may be formed on a sidewall of the dummy gate structure 215.

In example embodiments, a spacer layer may be formed on the dummy gate structure 15, the active fin 207 and the isolation layer 202, and the spacer layer may be anisotropically etched to form the gate spacer 220. The spacer layer may be formed of or include a nitride, e.g., silicon nitride, silicon oxynitride, silicon carbodiimide, etc.

As illustrated in FIG. 13, the gate spacer 220 may extend in the second direction together with the dummy gate structure 215.

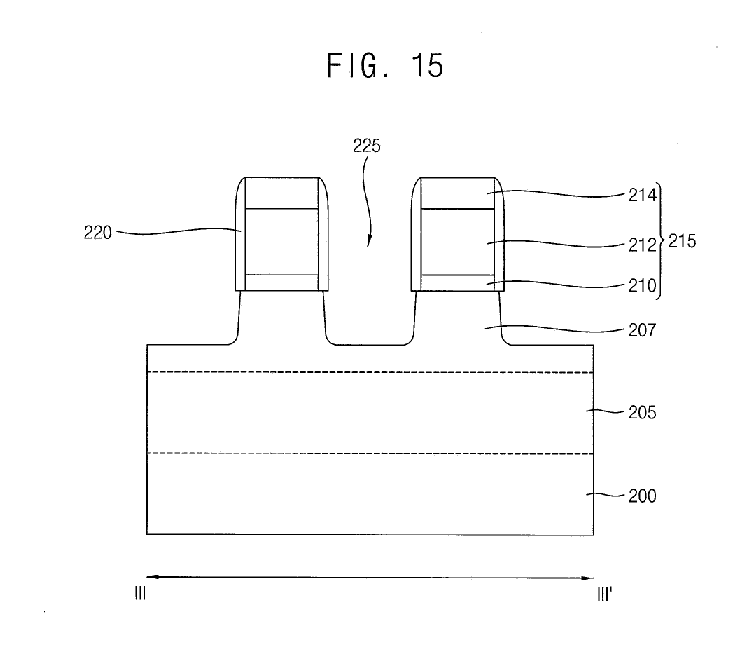

Referring to FIG. 15, an upper portion of the active fin 207 adjacent to the gate spacer 220 and/or the dummy gate structure 215 may be etched to form a recess 225.

In the etching process for the formation of the recess 225, the gate structure 220 may substantially serve as an etching mask. In example embodiments, an inner wall of the recess 225 may have a substantially “U”-shaped profile as illustrated in FIG. 15.

In some embodiments, the recess 225 may be expanded to a portion of the active pattern 205 below the top surface of the isolation layer 202.

In example embodiments, after forming the dummy gate spacer 220, and/or after forming the recess 225, a fourth cleaning treatment may be further performed to remove etching residues. As illustrated with reference to FIGS. 1 to 4, for example, a fluorine concentration of a collected solution after the third cleaning treatment may be measured, and the fourth cleaning treatment may be performed using a refreshed cleaning solution in which the organic fluoride, or a mixture of the organic fluoride and the organic acid may be replenished, based on a feed-back of an information of the fluorine concentration.

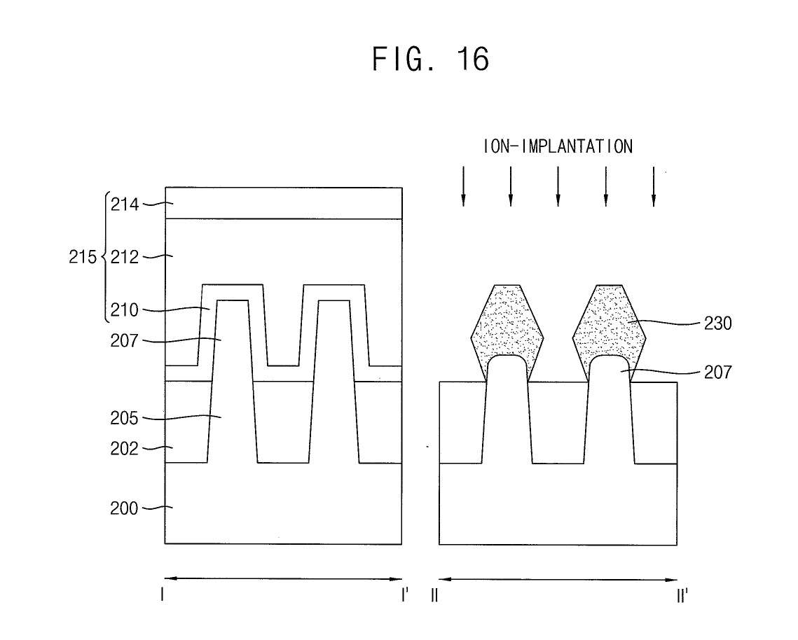

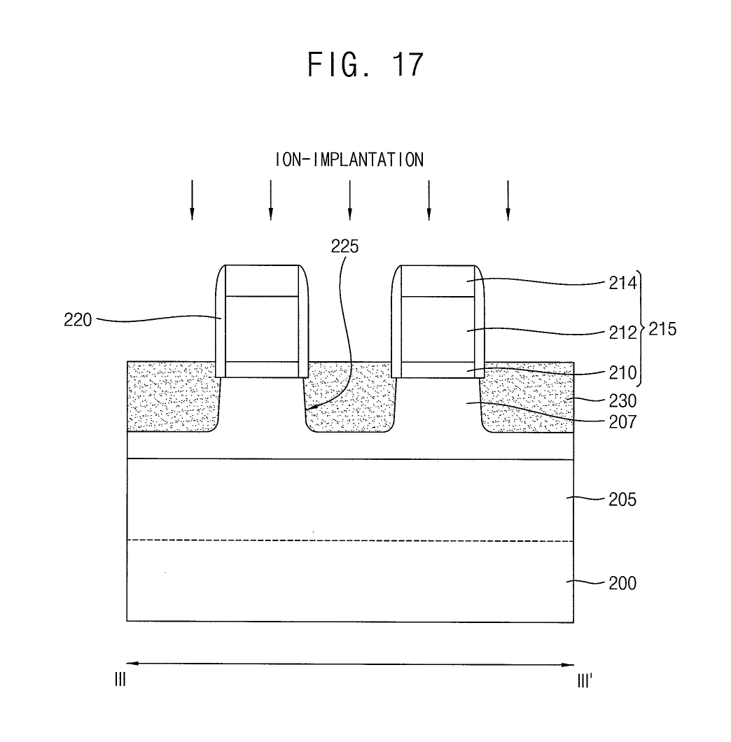

Referring to FIGS. 16 and 17, a source/drain layer 230 filling the recess 225 may be formed.

In example embodiments, a preliminary source/drain layer may be formed by a selective epitaxial growth (SEG) process using a top surface of the active fin 207 exposed by the recess 225 as a seed to fill the recess 225. An ion-implantation process may be performed so that the preliminary source/drain layer may be converted into the source/drain layer 230.

In some embodiments, P-type impurities such as boron (B) may be implanted by the implantation process. In this case, the source/drain layer 230 may serve as an impurity region of a PMOS-type FinFET. If the substrate 200 includes Si—Ge or Ge, a compressive stress may be applied through the source/drain layer 230 to improve a hole mobility in a PMOS channel.

In example embodiments, after forming the source/drain layer 230, a fifth cleaning treatment may be further performed to remove residues containing the impurities generated from the ion-implantation process. As illustrated with reference to FIGS. 1 to 4, for example, a fluorine concentration of a collected solution after the fourth cleaning treatment may be measured, and the fifth cleaning treatment may be performed using a refreshed cleaning solution in which the organic fluoride, or a mixture of the organic fluoride and the organic acid may be replenished, based on a feed-back of an information of the fluorine concentration.

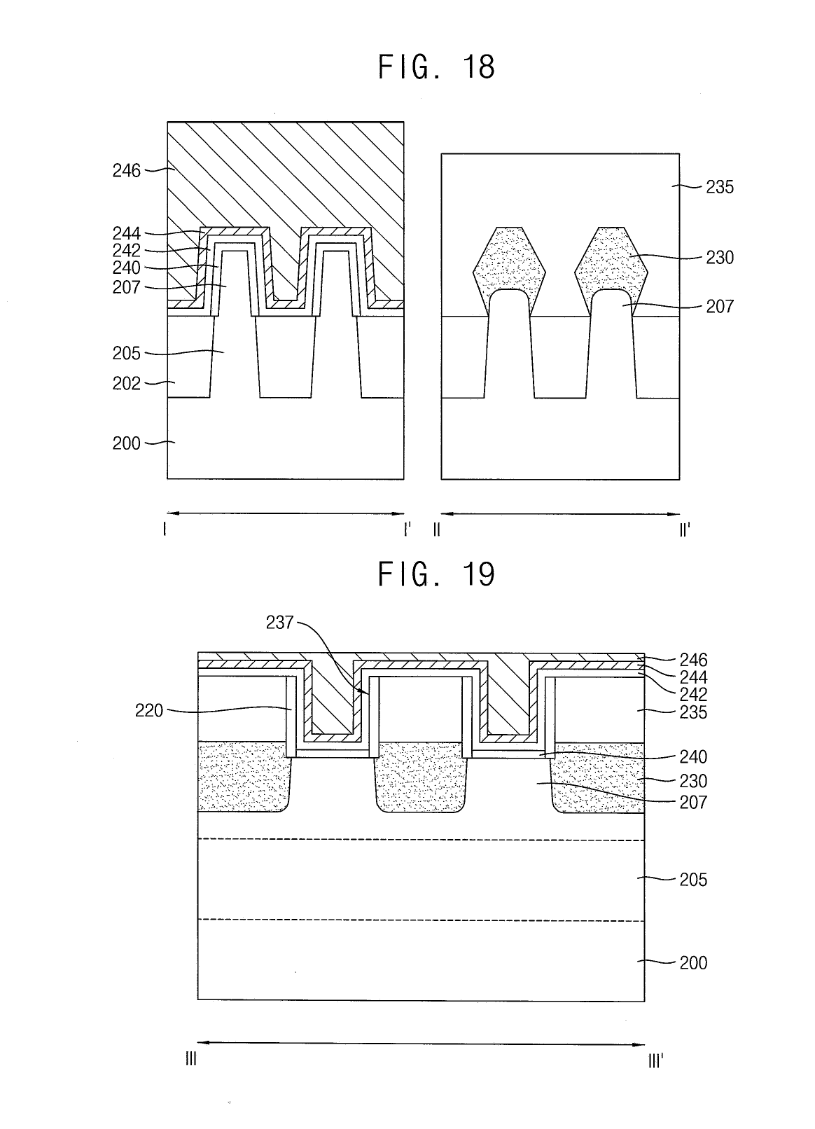

Referring to FIGS. 18 and 19, processes replacing the dummy gate structure 215 with a gate structure may be performed.

In example embodiments, an insulating interlayer 235 covering the dummy gate structure 215, the gate spacer 220 and the source/drain layers 230 may be formed on the active fin 207 and the isolation layer 202. An upper portion of the insulating interlayer 235 may be planarized by a CMP process until a top surface of the gate electrode 212 may be exposed.

The dummy gate mask 214 may be removed by the CMP process, and an upper portion of the gate spacer 220 may be also at least partially removed. The insulating interlayer 235 may be formed of or include, e.g., a silicon oxide-based material by a CVD process.

Subsequently, in an example embodiment, the dummy gate electrode 212 and the dummy gate insulation pattern 210 may be removed. Accordingly, a trench (not illustrated) exposing an upper portion of the active fin 207 may be formed between a pair of the gate spacers 220.

In example embodiments, after forming the trench, a sixth cleaning treatment may be further performed to remove etching residues remaining on an inner wall of the trench. As illustrated with reference to FIGS. 1 to 4, for example, a fluorine concentration of a collected solution after the fifth cleaning treatment may be measured, and the sixth cleaning treatment may be performed using a refreshed cleaning solution in which the organic fluoride, or a mixture of the organic fluoride and the organic acid may be replenished, based on feed-back relative to the fluorine concentration.

The exposed active fin 207 may be thermally oxidized to form an interface layer 240. A gate insulation layer 242 may be formed along a top surface of the insulating interlayer 235, the inner wall of the trench, and top surfaces of the interface layer 240 and the isolation layer 202, and a buffer layer 244 may be formed on the gate insulation layer 242. A gate electrode layer 246 filling a remaining portion of the trench may be formed on the buffer layer 244.

The gate insulation layer 242 may be formed of or include a metal oxide having a high dielectric constant (high-k) such as hafnium oxide, tantalum oxide and/or zirconium oxide. The buffer layer 244 may be included for adjusting a work function of a gate electrode. The buffer layer 244 may be formed of or include a metal nitride such as titanium nitride, tantalum nitride and/or aluminum nitride. The gate electrode layer 246 may be formed of or include a metal having a low electric resistance such as aluminum, copper, tungsten, or the like.

The gate insulation layer 242, the buffer layer 244 and the gate electrode layer 246 may be formed by a chemical vapor deposition (CVD) process, an ALD process, a physical vapor deposition (PVD) process, etc. In some embodiments, the interface layer 240 may be also formed by a deposition process such as a CVD process or an ALD process. In this case, the interface layer 240 may have a profile substantially the same as or similar to that of the gate insulation layer 242.

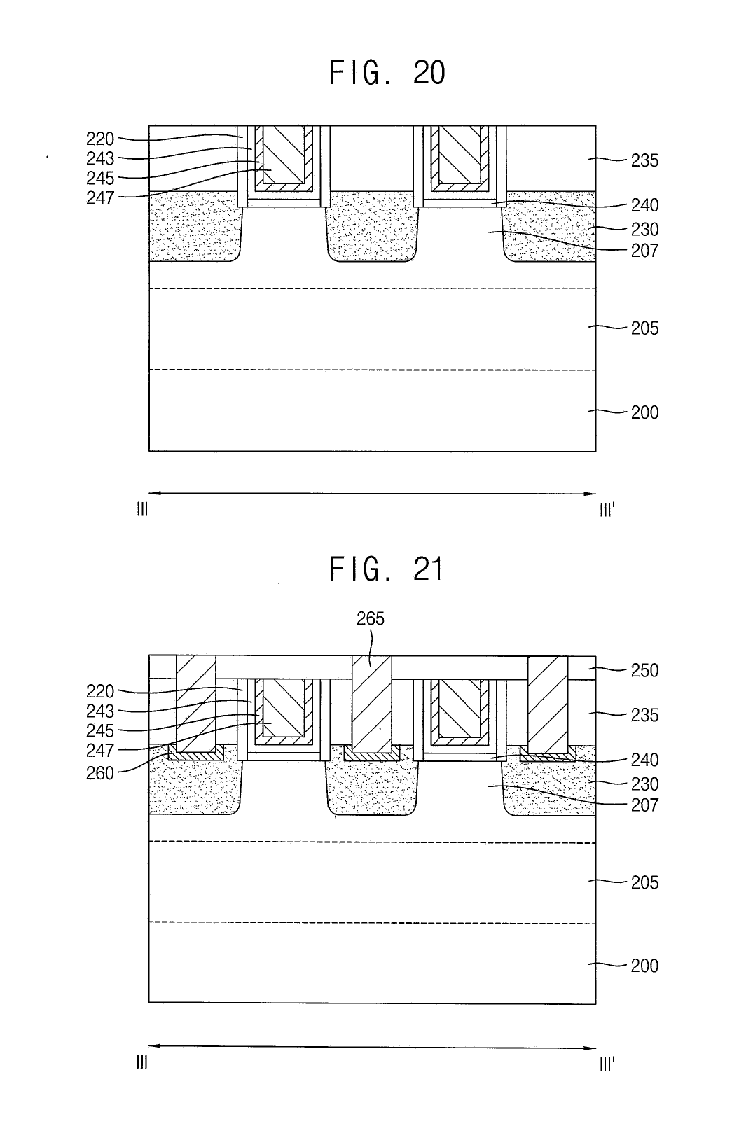

Referring to FIG. 20, upper portions of the gate electrode layer 246, the buffer layer 244 and the gate insulation layer 242 may be planarized by, e.g., a CMP process until the top surface of the insulating interlayer 235 may be exposed.

After the polarization process, a gate structure including the interface layer 240, a gate insulation pattern 243, a buffer pattern 245 and a gate electrode 247 may be defined in the trench. A PMOS transistor having a FinFET structure may be defined by the gate structure and the source/drain layer 230.

In example embodiments, after performing the CMP process, a seventh cleaning treatment may be further performed to remove polishing residues remaining on the insulating interlayer 235. As illustrated with reference to FIGS. 1 to 4, for example, a fluorine concentration of a collected solution after the sixth cleaning treatment may be measured, and the seventh cleaning treatment may be performed using a refreshed cleaning solution in which the organic fluoride, or a mixture of the organic fluoride and the organic acid may be replenished, based on a feed-back of an information of the fluorine concentration.

Referring to FIG. 21, a passivation layer 235 may be formed on the insulating interlayer 235, the gate spacers 220 and the gate structure. The passivation layer 250 may be formed of or include a nitride-based material such as silicon nitride or silicon oxynitride by a CVD process. A portion of the passivation layer 250 covering the gate structure may serve as a gate mask.

The passivation layer 250 and the insulating interlayer 235 may be at least partially etched to form a contact hole through which the source/drain layer 230 may be exposed. In some embodiments, while performing the etching process for forming the contact hole, an upper portion of the source/drain layer 230 may be partially removed. Accordingly, the contact hole may be at least partially inserted into the upper portion of the source/drain layer 230.

In some example embodiments, a silicide layer 260 may be formed at the upper portion of the source/drain layer 230 exposed through the contact hole. For example, a metal layer may be formed on the source/drain layer 230 exposed through the contact hole, and then a thermal treatment such as an annealing process may be performed thereon. A portion of the metal layer contacting the source/drain layer 230 may be transformed into a metal silicide by the thermal treatment. An unreacted portion of the metal layer may be removed to form the silicide layer 260.

The metal layer may be formed of or include, e.g., cobalt or nickel. The silicide layer 260 may include, e.g., cobalt silicide or nickel silicide.

In some embodiments, a plurality of the source/drain layers 230 may be exposed by one contact hole. The contact hole may be self-aligned with the gate spacer 220. In this case, an outer sidewall of the gate spacer 220 may be exposed by the contact hole.

A plug 265 electrically connected to the source/drain layer 230 may be formed in the contact hole.

For example, a conductive layer sufficiently filling the contact holes may be formed on the passivation layer 250. An upper portion of the conductive layer may be planarized by a CMP process until a top surface of the passivation layer 250 may be exposed to form the plugs 265. The conductive layer may be formed of or include a metal, a metal nitride or a doped polysilicon. In some embodiments, a barrier layer including a metal nitride such as titanium nitride may be further formed along an inner wall of the contact hole before forming the conductive layer.

The plug 265 may contact the silicide layer 260. Thus, an electrical resistance between the plug 265 and the source/drain layer 230 may be reduced. In some embodiments, the plug 265 may extend in the second direction, and may be electrically connected to a plurality of the source/drain layers 230.

In some embodiments, a back-end-of-line (BEOL) process for a wiring build-up may be further performed on the passivation layer 250 and the plug 265. Before performing the BEOL, process, a cleaning treatment may be further performed to remove polishing residues remaining on the passivation layer 250 and the plug 265. In example embodiments, the cleaning treatment may be performed utilizing the cleaning process system illustrated with reference to FIGS. 1 to 4.

As described above, a plurality of the cleaning treatments in a fabrication of, e.g., a FinFET semiconductor device may be performed utilizing the cleaning process system according to example embodiments. Therefore, a desired cleaning efficiency may be achieved while suppressing damages of various structures included in the semiconductor device.

According to example embodiments of the present inventive concepts, a semiconductor substrate may be cleaned using an organic cleaning solution that may include an organic fluoride, an organic acid and an organic solvent, and a fluorine concentration of a collected solution from the organic cleaning solution may be measured. When the fluorine concentration is less than a desired, or alternatively predetermined threshold concentration, the organic fluoride may be replenished into the organic cleaning solution until a target concentration is obtained. The organic acid may be replenished together with the organic fluoride so that a cleaning capability may be recovered more rapidly.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor cleaning system, comprising:
a process chamber configured to hold a semiconductor substrate;
a cleaning solution supply unit configured to supply a cleaning solution to the process chamber, the cleaning solution including at least an organic fluoride, an organic acid and an organic solvent;
a recycling unit configured to collect the cleaning solution from the process chamber;
a first concentration measuring unit configured to measure a fluorine concentration of the collected cleaning solution; and
a sub-cleaning solution supply unit configured to supply the organic fluoride to the cleaning solution supply unit based on the measured fluorine concentration.

2. The semiconductor cleaning system of claim 1, wherein the organic fluoride includes an alkyl ammonium fluoride, and the organic acid includes an organic sulfonic acid.

3. The semiconductor cleaning system of claim 1, wherein
the cleaning solution supply unit includes a cleaning solution supply bath configured to store the cleaning solution, and a supply flow path configured to provide the cleaning solution to the process chamber,
the recycling unit includes,
a first recycling flow path configured to collect the cleaning solution from the process chamber;
a recycling bath configured to store the collected cleaning solution from the first recycling flow path; and
a second recycling flow path configured to provide the collected cleaning solution from the recycling bath to the cleaning solution supply unit.

4. The semiconductor cleaning system of claim 3, wherein the recycling unit further includes a filter at a portion of the first recycling flow path, the filter being configured to remove at least one of moisture and cleaning residues from the collected cleaning solution.

5. The semiconductor cleaning system of claim 1, further comprising:
a control unit coupled to the first concentration measuring unit and the sub-cleaning solution supply unit, the control unit storing a threshold fluorine concentration;
wherein a compensation signal of the organic fluoride is transferred from the control unit to the sub-cleaning solution supply unit when the fluorine concentration is less than the threshold fluorine concentration.

6. The semiconductor cleaning system of claim 5, wherein the sub-cleaning solution supply unit includes:
a sub-cleaning solution supply bath configured to store a crude organic fluoride solution:
a sub-supply flow path configured to supply the organic fluoride from the sub-cleaning solution supply bath to the cleaning solution supply unit; and
a flow rate controller at a portion of the sub-supply flow path.

7. The semiconductor cleaning system of claim 6, wherein the flow rate controller is configured to provide the organic fluoride as a plurality of pulses.

8. The semiconductor cleaning system of claim 5, further comprising:
a second concentration measuring unit configured to measure a fluorine concentration of the cleaning solution, the second concentration measuring unit being coupled to the cleaning solution supply unit.

9. The semiconductor cleaning system of claim 8, wherein the control unit is coupled to the second concentration measuring unit, and
the control unit is configured to transfer a supply signal of the cleaning solution in the process chamber to the cleaning solution supply unit when the fluorine concentration of the cleaning solution reaches a target fluorine concentration.

10. The semiconductor cleaning system of claim 1, wherein the sub-cleaning solution supply unit is configured to supply the organic acid together with the organic fluoride.

11. The semiconductor cleaning system of claim 10, wherein the sub-cleaning solution supply unit includes:
a first sub-cleaning solution supply unit configured to store and to supply a crude organic fluoride solution; and
a second sub-cleaning solution supply unit configured to supply a crude organic acid solution

12. The semiconductor cleaning system of claim 10, wherein an amount of the organic acid of the cleaning solution stored in the cleaning solution supply unit is in a range of about 4 weight percent to about 12 weight percent based on a total weight of the cleaning solution.

13. The semiconductor cleaning system of claim 1, wherein the semiconductor substrate includes at least one of germanium and a group III-V compound.

14. A semiconductor cleaning system, comprising:
a process chamber configured to hold a semiconductor substrate;
a cleaning solution supply unit configured to supply an organic cleaning solution to the process chamber, the organic cleaning solution including at least an organic fluoride, an organic acid and an organic solvent, the organic cleaning solution being substantially devoid of water;
a recycling unit configured to collect the organic cleaning solution discharged from the process chamber;
a concentration measuring unit configured to measure a fluorine concentration of the collected organic cleaning solution; and
a sub-cleaning solution supply unit configured to supply a mixture consisting essentially of the organic fluoride and the organic acid to the cleaning solution supply unit based on the measured fluorine concentration.

15. The semiconductor cleaning system of claim 14, wherein the concentration measuring unit is further configured to measure an organic acid concentration of the collected solution.

16. A cleaning system, comprising:
a concentration measuring unit configured to measure a fluorine concentration and an acid concentration of an organic cleaning solution collected in a collector; and
a first sub-cleaning solution supplier configured to supply organic fluoride to a cleaning solution supplier based on the measured fluorine concentration;
the organic cleaning solution being substantially devoid of an inorganic compound.

17. The cleaning system of claim 16, further comprising:
a second sub-cleaning solution supplier configured to supply an organic acid to the cleaning solution supplier based on the measured acid concentration.

18. The cleaning system of claim 16, wherein the organic cleaning solution comprises at least one of organic fluoride, an organic acid and an organic solvent.

19. The cleaning system of claim 18, wherein at least one of the organic fluoride includes an alkyl ammonium fluoride and the organic acid includes an organic sulfonic acid.

20. The cleaning system of claim 16, further comprising:
a control unit configured to control the measurement of the fluorine concentration and of the acid concentration, and to control the supply of the organic fluoride and of the organic acid to the cleaning solution supplier based on the measurement of the fluorine concentration and of the acid concentration.
